(19) United States
(12) Patent Application Publication
(10) Pub. No.: US 2022/0199721 A1
(43) Pub. Date: Jun. 23, 2022

(54) METHOD OF MANUFACTURING POLYCRYSTALLINE SILICON LAYER, DISPLAY DEVICE, AND METHOD OF MANUFACTURING DISPLAY DEVICE

(71) Applicant: Samsung Display Co., Ltd., Yongin-si (KR)

(72) Inventors: Jong Jun BAEK, Seoul (KR); Jong Oh Seo, Seoul (KR)

(21) Appl. No.: 17/471,055

(22) Filed: Sep. 9, 2021

(30) Foreign Application Priority Data
Dec. 18, 2020 (KR) 10-2020-0178646

(51) Int. Cl. H01L 27/32; H01L 29/66; H01L 29/786

(52) U.S. Cl. CPC H01L 27/3258; H01L 29/6675; H01L 2227/323; H01L 29/78663; H01L 29/78696; H01L 29/78672

(57) ABSTRACT

A method of manufacturing a polycrystalline silicon layer, includes forming an amorphous silicon layer on a substrate; doping the amorphous silicon layer with at least one impurity; cleaning the amorphous silicon layer with hydrofluoric acid; rinsing the amorphous silicon layer with hydrogen-added deionized water; and forming a polycrystalline silicon layer by irradiating a laser beam onto the amorphous silicon layer.

This application claims priority from and the benefit of Korean Patent Application No. 10-2020-0178646 Filed on Dec. 18, 2020, which is hereby incorporated by reference for all purposes as if fully set forth herein.

### BACKGROUND

### Field

Embodiments of the invention relate generally to a method of manufacturing a polycrystalline silicon layer, a display device, and a method of manufacturing the display device.

### Discussion of the Background

An active matrix (AM) type organic light-emitting display device may include a pixel circuit for each pixel, and the pixel circuit may include a thin film transistor using silicon. Amorphous silicon or polycrystalline silicon may be used as the silicon forming the thin film transistor.

An amorphous silicon thin film transistor (a-Si TFT) used in the pixel circuit may have a low electron mobility equal to or less than 1 cm²/Vs because an active layer forming a source, a drain, and a channel is formed of amorphous silicon. Accordingly, recently, there is a trend to replace the a-Si TFT with a polycrystalline silicon TFT (poly-Si TFT). The poly-Si TFT has a higher electron mobility than the a-Si TFT, and has an excellent stability against light irradiation. Therefore, the poly-Si TFT may be appropriate to be used as an active layer of a driving transistor and/or a switching transistor of the AM type organic light-emitting display device.

Such a poly-Si TFT may be manufactured by various methods, which may be broadly divided into a method of directly depositing polycrystalline silicon and a method of depositing amorphous silicon and then crystallizing the amorphous silicon.

The methods of directly depositing polycrystalline silicon include chemical vapor deposition (CVD), sputtering, vacuum evaporation, and the like.

The methods of depositing amorphous silicon and then crystallizing the amorphous silicon include solid phase crystallization (SPC), excimer laser crystallization (ELC), metal-induced crystallization (MIC), metal-induced lateral crystallization (MILC), sequential lateral solidification (SLS), and the like.

The above information disclosed in this Background section is only for understanding of the background of the inventive concepts, and, therefore, it may contain information that does not constitute prior art.

### SUMMARY

Devices constructed/methods according to illustrative implementations of the invention are capable of disposing a hydrofluoric acid over an entire surface of an amorphous silicon layer, such that, when a polycrystalline silicon layer is formed, it is possible to prevent in advance defects of the polycrystalline silicon layer that may otherwise occur due to the circular stains remaining on the polycrystalline silicon layer.

Embodiments of the inventive concepts provide a method of manufacturing a polycrystalline silicon layer in which circular stains of the polycrystalline silicon layer are improved.

Embodiments of the inventive concepts also provide a display device including a thin film transistor having an active pattern in which circular stains are improved.

Embodiments of the inventive concepts further provide a method of manufacturing a display device in which circular stains of an active pattern are improved.

Additional features of the inventive concepts will be set forth in the description which follows, and in part will be apparent from the description, or may be learned by practice of the inventive concepts.

A method of manufacturing a polycrystalline silicon layer according to an embodiment for solving at least of the above problems includes forming an amorphous silicon layer on a substrate; doping the amorphous silicon layer with at least one impurity; cleaning the amorphous silicon layer with hydrofluoric acid; rinsing the amorphous silicon layer with hydrogen-added deionized water; and forming a polycrystalline silicon layer by irradiating a laser beam onto the amorphous silicon layer.

The at least one impurity may include phosphorus (P), and may be doped on the entire surface of the amorphous silicon layer.

The at least one impurity may be doped through an ion implantation method, and a dose of the at least one impurity may be 1.0 e¹² to 1.0 e¹³ per cm³.

A native oxide layer may be formed on the amorphous silicon layer, and the at least one impurity may induce bonding between silicon (Si) in the amorphous silicon layer and oxygen (O) in the native oxide layer to form a silicon oxide layer between the native oxide layer and the amorphous silicon layer.

The native oxide layer may be removed in the cleaning of the amorphous silicon layer, and the silicon oxide layer may not be removed.

The hydrofluoric acid may contain about 0.5% hydrogen fluoride.

The amorphous silicon layer may be cleaned for 40 seconds to 54 seconds.

The hydrogen-added deionized water may have a hydrogen concentration of about 1.0 ppm.

An energy density of the laser beam may range from 450 mJ/cm² to 500 mJ/cm².

The laser beam may be about 480 μm, and a scan pitch of the laser beam may range from 9 μm to 30 μm.

An effective value of a surface roughness of the polycrystalline silicon layer may be 4 nm or less.

A protrusion may be formed on a surface of the polycrystalline silicon layer, and the protrusion may have a pointed shape.

The grains of the polycrystalline silicon layer may be randomly arranged.

A display device according to another embodiment for solving at least one of the above problems includes a substrate; a thin film transistor disposed on the substrate; and a display element disposed on the thin film transistor, wherein the thin film transistor includes: an active pattern disposed on the substrate; a gate insulating film disposed on the active pattern; and a gate electrode disposed on the gate insulating film, wherein an effective value of a surface roughness of the active pattern is 4 nm or less, and a silicon oxide layer is further disposed between the active pattern and the gate insulating film.

The active pattern may include a source region, a drain region, and a channel region formed therebetween.

The gate electrode may overlap the channel region of the active pattern.

The thin film transistor may be disposed on the gate electrode, and the thin film transistor further may include a source electrode and a drain electrode electrically connected to the source region and the drain region of the active pattern, respectively.

The display element may include a first electrode electrically connected to the thin film transistor, an organic light-emitting layer disposed on the first electrode, and a second electrode disposed on the organic light-emitting layer.

A method of manufacturing a display device according to another embodiment for solving at least one of the above problems includes forming an amorphous silicon layer on a substrate; doping the amorphous silicon layer with at least one impurity; cleaning the amorphous silicon layer with hydrofluoric acid; rinsing the amorphous silicon layer with hydrogen-added deionized water; forming a polycrystalline silicon layer by irradiating a laser beam onto the amorphous silicon layer; etching the polycrystalline silicon layer and forming a polycrystalline silicon pattern; forming a gate insulating film on the polycrystalline silicon pattern; forming a gate electrode on the gate insulating film; partially implanting ions into the polycrystalline silicon pattern and forming an active pattern; and forming a display element on the gate electrode.

The at least one impurity may include phosphorus (P) and be doped on the entire surface of the amorphous silicon layer, the at least one impurity doped through an ion implantation method, with a dose of the at least one impurity being 1.0 e¹² to 1.0 e¹³ per cm³.

Specific matters of other embodiments are included in detailed descriptions and drawings.

It is to be understood that both the foregoing general description and the following detailed description are illustrative and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate illustrative embodiments of the invention, and together with the description serve to explain the inventive concepts.

FIG. 1 is a flowchart showing a method of manufacturing a polycrystalline silicon layer according to an embodiment of the inventive concepts.

FIGS. 2, 3, 4, 5, 6, 7, 8, 9, and 10 are views showing the method of manufacturing the polycrystalline silicon layer according to an embodiment.

FIG. 11 is a cross-sectional view showing a thin film transistor substrate according to an embodiment.

FIGS. 12, 13, 14, 15, 16, 17, and 18 are cross-sectional views showing a method of manufacturing the thin film transistor substrate of FIG. 11.

FIG. 19 is a circuit diagram showing one pixel of a display device according to an embodiment.

FIG. 20 is a cross-sectional view showing the display device according to an embodiment.

FIGS. 21 and 22 are cross-sectional views showing a method of manufacturing the display device of FIG. 20.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing illustrative features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis described below is not limited to an axis of a rectangular coordinate system, such as the x-axis of an x-y-z three-axis coordinate system, and may be interpreted in a broader sense. For example, the D1-axis may be perpendicular to another axis such as a y-axis or a z-axis of an x-y-z three-axis coordinate system, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

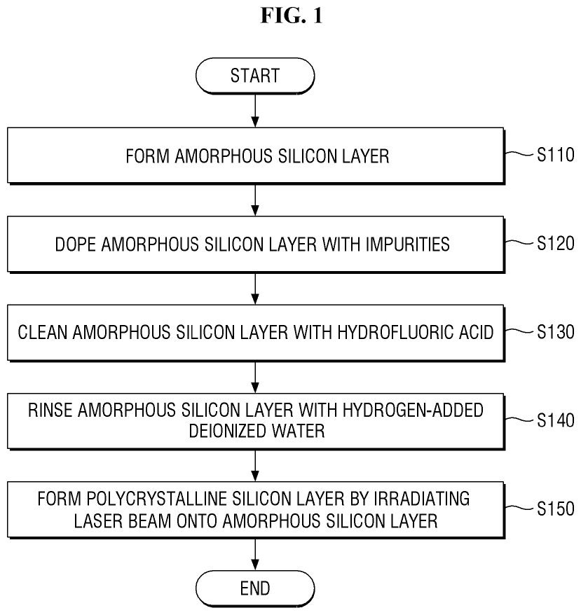

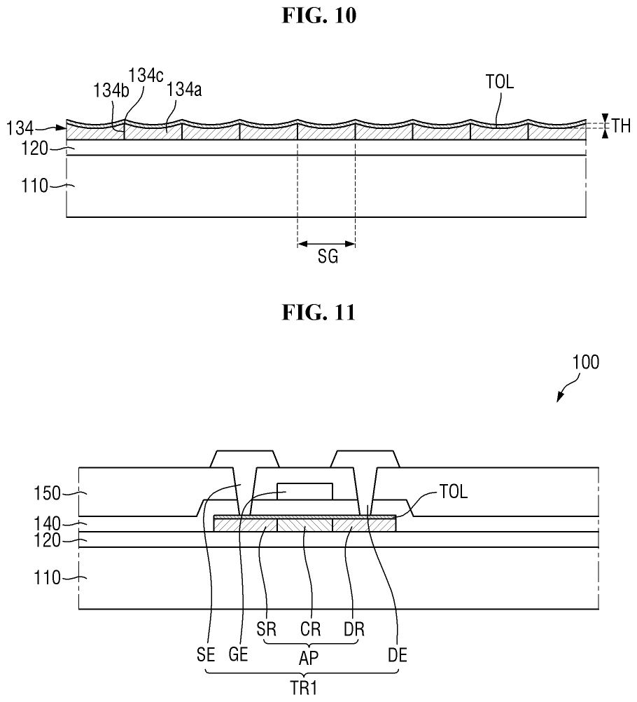

Hereinafter, a method of manufacturing a polycrystalline silicon layer according to an embodiment will be described with reference to FIGS. 1 to 10.

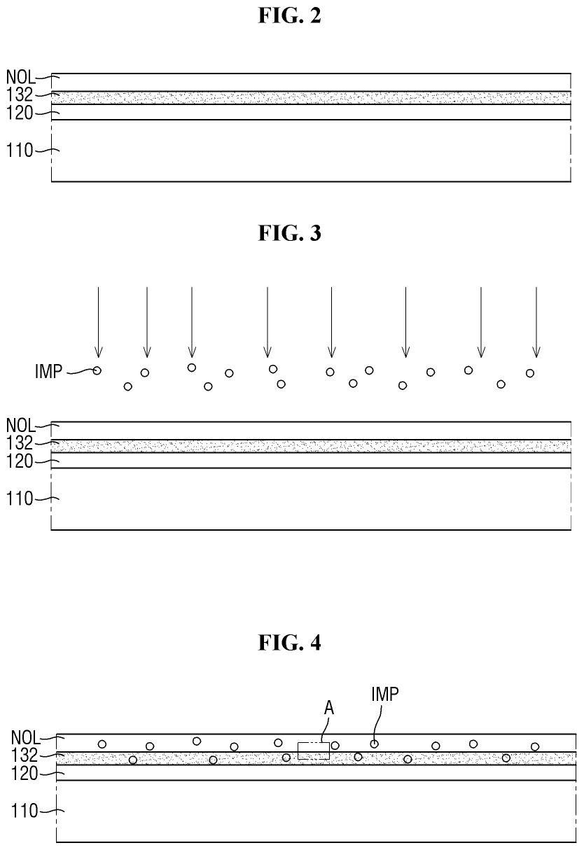

FIG. 1 is a flowchart showing a method of manufacturing a polycrystalline silicon layer according to an embodiment that is constructed according to principles of the invention. FIGS. 2 to 10 are views showing the method of manufacturing the polycrystalline silicon layer according to an embodiment.

Referring to FIGS. 1 and 2, an amorphous silicon layer 132 may be formed on a substrate 110 (S110).

The substrate 110 may be an insulating substrate including glass, quartz, ceramic, or the like. In an embodiment, the substrate 110 may also be a flexible insulating substrate containing plastic such as polyethylene terephthalate (PET), polyethylene naphthalate (PEN), polyether ether ketone (PEEK), polycarbonate (PC), polyarylate, polyether sulfone (PES), or polyimide (PI).

A buffer layer 120 may be formed on the substrate 110. The buffer layer 120 may provide a flat surface on the substrate 110, and may prevent impurities from penetrating through the substrate 110. For example, the buffer layer 120 may be formed of silicon oxide, silicon nitride, or the like.

The amorphous silicon layer 132 may be formed on the buffer layer 120. The amorphous silicon layer 132 may be formed by a method such as low pressure chemical vapor deposition (LPCVD), atmospheric pressure chemical vapor deposition (APCVD), plasma enhanced chemical vapor deposition (PECVD), sputtering, vacuum evaporation, or the like.

A native oxide layer NOL may be formed on the amorphous silicon layer 132. The native oxide layer NOL may be formed by exposing an upper portion of the amorphous silicon layer 132 to air. When the native oxide layer NOL remains on the amorphous silicon layer 132, a protrusion having a relatively large thickness may be formed on a surface of a polycrystalline silicon layer by the native oxide layer NOL during the crystallization of the amorphous silicon layer 132 for forming the polycrystalline silicon layer.

Referring to FIGS. 1, 3, and 4, the amorphous silicon layer 132 may be doped with at least one impurity (S120). Impurities IMP may be a Group V element. In an embodiment, the impurities IMP may include phosphorus (P). The impurities IMP may be doped on the entire surface of the amorphous silicon layer 132. Further, the impurities IMP may be doped into the native oxide layer NOL.

The impurities IMP may be doped through an ion implantation method. When using the ion implantation method, the impurities IMP in an ionic state are accelerated to tens to several hundreds keV and implanted into the amorphous silicon layer 132. A dose of the impurities IMP may be 1.0 e12 to 1.0 e13 per 1 cm³.

The impurities IMP may induce bonding between silicon (Si) in the amorphous silicon layer 132 and oxygen (O) in the native oxide layer NOL to form a silicon oxide layer TOL between the native oxide layer NOL and the amorphous silicon layer 132.

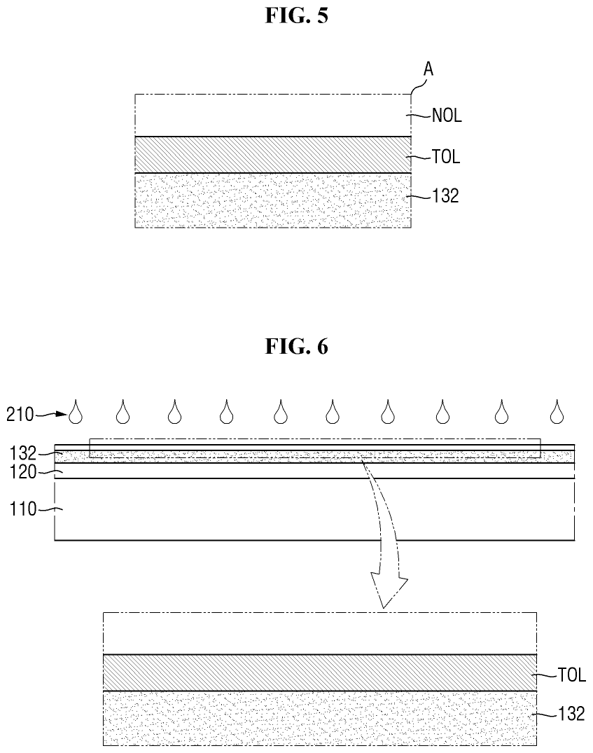

That is, as shown in an enlarged view of FIG. 4, the silicon oxide layer TOL may be formed between the native oxide layer NOL and the amorphous silicon layer 132.

Referring to FIGS. 1, 6, and 7, the amorphous silicon layer 132 may be cleaned (S130).

The amorphous silicon layer 132 may be cleaned using hydrofluoric acid 210. The hydrofluoric acid 210 may be an aqueous solution in which hydrogen fluoride (HF) is dissolved. For example, the hydrofluoric acid 210 may contain about 0.5% hydrogen fluoride. The native oxide layer NOL formed on the amorphous silicon layer 132 may be removed by cleaning the amorphous silicon layer 132 with the hydrofluoric acid 210.

Even though the amorphous silicon layer 132 is cleaned with the hydrofluoric acid 210, a portion of the silicon oxide layer TOL may remain without being removed on a surface of the amorphous silicon layer 132.

In an embodiment, the amorphous silicon layer 132 may be cleaned by the hydrofluoric acid 210 for about 40 seconds to about 54 seconds. When the amorphous silicon layer 132 is cleaned for less than about 40 seconds, the native oxide layer NOL formed on the amorphous silicon layer 132 may not be sufficiently removed. In addition, when the amorphous silicon layer 132 is cleaned for longer than about 54 seconds, the amorphous silicon layer 132 may be affected by the hydrofluoric acid 210.

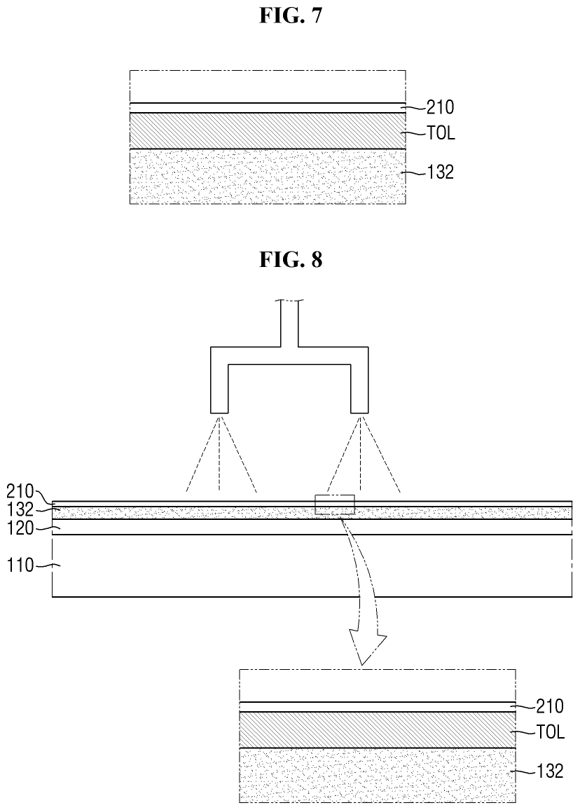

The silicon oxide layer TOL remaining on the surface of the amorphous silicon layer 132 without being removed may have hydrophilicity. In FIGS. 6 and 7, the silicon oxide layer TOL is described as a layer separated from the amorphous silicon layer 132, but when interpreting that the silicon oxide layer TOL is included in the surface of the amorphous silicon layer 132, it can be seen that the surface of the amorphous silicon layer 132 is hydrophilized through the silicon oxide layer TOL. Even when interpreting the above-described silicon oxide layer TOL and the amorphous silicon layer 132 as separate layers, or interpreting the silicon oxide layer TOL as being included in the surface of the amorphous silicon layer 132, as shown in FIG. 7, the hydrofluoric acid 210 may be disposed over the entire surface of the amorphous silicon layer 132.

When the amorphous silicon layer 132 is not doped with impurities, the native oxide layer NOL formed on the surface of the amorphous silicon layer 132 may be removed through the cleaning of the amorphous silicon layer 132 (S130), and the surface of the amorphous silicon layer 132 may be hydrophobized. In this case, when the amorphous silicon layer 132 is cleaned (S130), the hydrofluoric acid 210 may be formed on the surface of the amorphous silicon layer 132 with a contact angle of about 47 degrees or more. Accordingly, when forming a polycrystalline silicon layer to be described later, circular stains remain on the polycrystalline silicon layer, which may cause defects in the polycrystalline silicon layer.

However, in the case of the embodiment, as described above, since the silicon oxide layer TOL remaining on the surface of the amorphous silicon layer 132 without being unremoved has hydrophilicity, the hydrofluoric acid 210 may be disposed over the entire surface of the amorphous silicon layer 132. Accordingly, when the polycrystalline silicon layer is formed, it is possible to prevent in advance defects of the polycrystalline silicon layer that may otherwise occur due to the circular stains remaining on the polycrystalline silicon layer.

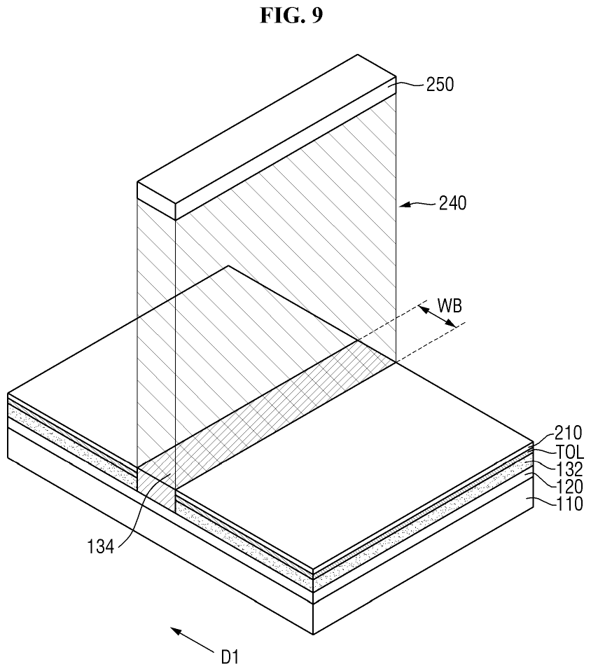

Referring to FIGS. 1 and 8, the amorphous silicon layer 132 may be rinsed (S140).

The amorphous silicon layer 132 may be rinsed using hydrogen-added deionized water 220. For example, the hydrogen-added deionized water 220 may have a hydrogen concentration of about 1.0 ppm. For example, while moving the substrate 110 under a fixed spray 230, the hydrogen-added deionized water 220 may be supplied to the amorphous silicon layer 132 through the spray 230. The amorphous silicon layer 132 may be rinsed with the hydrogen-added deionized water 220 to remove the hydrofluoric acid 210 remaining on the amorphous silicon layer 132.

Compared to a case of rinsing the amorphous silicon layer 132 using deionized water to which hydrogen is not added, most of the hydrofluoric acid 210 on the surface of the silicon oxide layer TOL may be removed by rinsing the amorphous silicon layer 132 using the hydrogen-added deionized water 220 as in the embodiment described herein, but, as shown in FIG. 8, the hydrofluoric acid 210 may remain very thin on the surface of the silicon oxide layer TOL.

Referring to FIGS. 1, 9, and 10, a polycrystalline silicon layer 134 may be formed (S150).

The polycrystalline silicon layer 134 may be formed by irradiating a laser beam 240 onto the amorphous silicon layer 132. A laser 250 may intermittently generate the laser beam 240 to irradiate the amorphous silicon layer 132. For example, the laser 250 may be an excimer laser that generates the laser beam 240 with short wavelength, high power, and high efficiency. The excimer laser may include, for example, an inert gas, an inert gas halide, a mercury halide, an inert gas oxide compound, and a polyatomic excimer. For example, the inert gas may be Are, Kr₂, Xe₂, etc., the inert gas halide may be ArF, ArCl, KrF, KrCl, XeF, XeCl, etc., the mercury halide may be HgCl, HgBr, HgI, etc., the inert gas oxide compound may be ArO, KrO, XeO, etc., and the polyatomic excimer may be Kr₂F, Xe₂F, etc.

The amorphous silicon layer 132 may be crystallized into the polycrystalline silicon layer 134 by irradiating the laser beam 240 onto the amorphous silicon layer 132 from the laser 250 while moving the substrate 110 along a first direction D1. The laser 250 may irradiate a laser beam 240 having an energy density of about 450 mJ/cm² to about 500 mJ/cm² onto the amorphous silicon layer 132. In an embodiment, a width WB of the laser beam 240 in the first direction D1 may be about 480 μm, and a scan pitch of the laser beam 240 in the first direction D1 may be about 9 μm to about 30 μm. For example, when the scan pitch is about 24 μm, the laser beam 240 may be irradiated about 24 times onto a predetermined region of the amorphous silicon layer 132. As shown in FIG. 5, the amorphous silicon layer 132 may be converted into the polycrystalline silicon layer 134 in a region in which a crystallization process is performed using the laser beam 240.

When the laser beam 240 is irradiated onto the amorphous silicon layer 132 that is in a solid state, the amorphous silicon layer 132 may absorb heat to change to a liquid state, and then may discharge heat to change to the solid state again. In this case, a crystal may grow from a crystal seed to form a grain 134a. When there is a difference in cooling rate in a process of changing the amorphous silicon layer 132 from the liquid state to the solid state, a grain boundary 134b may be formed in a region having a low cooling rate because the grain 134a grows from a region having a high cooling rate toward a region having a low cooling rate.

When the polycrystalline silicon layer 134 is formed (S150), all the hydrofluoric acid 210 remaining thin on the surface of the silicon oxide layer TOL may be substantially removed. As described above, when the amorphous silicon layer 132 is not doped with impurities, the native oxide layer NOL formed on the surface of the amorphous silicon layer 132 is removed by cleaning the amorphous silicon layer 132 (S130), and the surface of the amorphous silicon layer 132 is hydrophobized, and when the polycrystalline silicon layer is formed, circular stains remain on the polycrystalline silicon layer 134, which may cause defects in the polycrystalline silicon layer 134.

However, in the case of the embodiment described herein, since the silicon oxide layer TOL remaining on the surface of the amorphous silicon layer 132 without being removed has hydrophilicity, the hydrofluoric acid 210 may be disposed over the entire surface of the amorphous silicon layer 132, and when the polycrystalline silicon layer 134 is formed, it is possible to prevent circular stains from remaining on the polycrystalline silicon layer 134 in advance.

A plurality of grains 134a may be formed in the polycrystalline silicon layer 134. The grains 134a may be randomly arranged on a plane. Each of the grains 134a may be formed to have a size of about 150 nm to about 200 nm.

A protrusion 134c may be formed at the grain boundary 134b on the surface of the polycrystalline silicon layer 134 on which the crystallization process has been performed. While the amorphous silicon layer 132 melted by the laser beam 240 is recrystallized around the grain 134a, the protrusion 134c may be formed at the grain boundary 134b.

The protrusion 134c may protrude upward from the surface of the polycrystalline silicon layer 134, and may have a pointed shape. The protrusion 134c may have a constant thickness TH corresponding to a distance from the surface of the polycrystalline silicon layer 134 to an end of the protrusion 134c.

An effective value of a surface roughness of the polycrystalline silicon layer 134 may be about 4 nm or less. In this case, the effective value of thicknesses of the protrusions 134c formed on the surface of the polycrystalline silicon layer 134 may be about 4 nm or less.

According to an embodiment, the thickness of the protrusion 134c formed on the surface of the polycrystalline silicon layer 134 may be reduced, and the polycrystalline silicon layer 134 having a relatively small surface roughness may be formed by performing the cleaning process using the hydrofluoric acid 210 and the rinsing process using the hydrogen-added deionized water 220 before the crystallization process.

The cleaning process, rinsing process, and crystallization process for forming the polycrystalline silicon layer 134 have been described above, but it is also possible that processes for forming the polycrystalline silicon layer 134 are added in addition to the processes, or some of the processes are omitted. In addition, it is also possible that the processes are performed multiple times. For example, the crystallization process may be performed twice or more.

Hereinafter, a thin film transistor substrate and a method of manufacturing the same according to an embodiment will be described with reference to FIGS. 11 to 18.

FIG. 11 is a cross-sectional view showing a thin film transistor substrate according to an embodiment.

Referring to FIG. 11, a thin film transistor substrate 100 according to an embodiment may include a substrate 110 and a thin film transistor TR1 disposed on the substrate 110. The thin film transistor TR may include an active pattern AP, a gate insulating film 140, a gate electrode GE, a source electrode SE, and a drain electrode DE that are sequentially stacked. The thin film transistor TR1 may perform a switching operation of flowing a current through the active pattern AP based on a signal applied to the gate electrode GE.

The thin film transistor TR1 may have a top gate structure in which the gate electrode GE is positioned above the active pattern AP. However, the embodiment described herein is not limited thereto, and the thin film transistor TR1 may have a bottom gate structure in which the gate electrode is positioned below the active pattern.

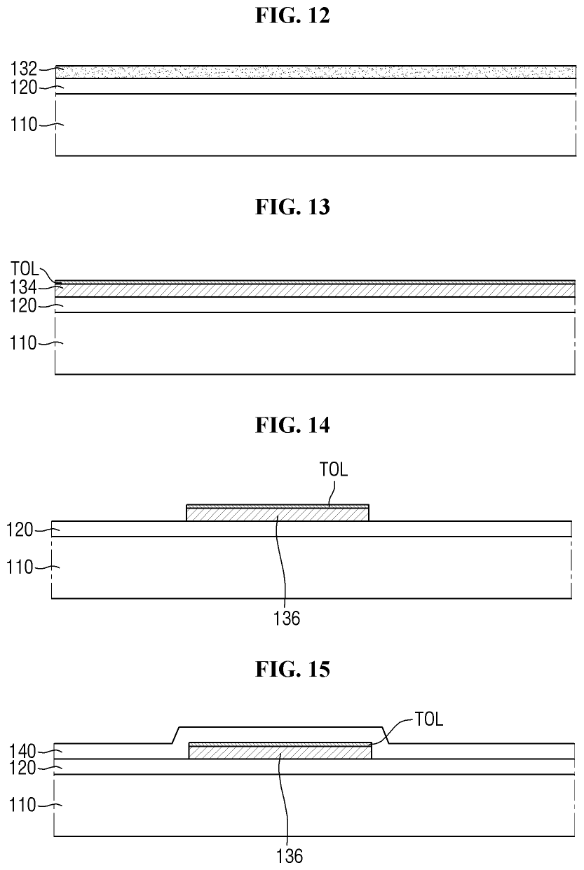

FIGS. 12 to 18 are cross-sectional views showing a method of manufacturing the thin film transistor substrate of FIG. 11.

Hereinafter, in describing the method of manufacturing the thin film transistor substrate according to an embodiment, a description of a portion overlapping the method of manufacturing a polycrystalline silicon layer according to an embodiment will be omitted for ease in explanation of the embodiment.

Referring to FIG. 12, an amorphous silicon layer 132 may be formed on the substrate 110.

The substrate 110 may be an insulating substrate including glass, quartz, ceramic, or the like. In an embodiment, the substrate 110 may also be a flexible insulating substrate containing plastic such as polyethylene terephthalate, polyethylene naphthalate, polyether ether ketone, polycarbonate, polyarylate, polyether sulfone, or polyimide. In this case, a barrier layer containing silicon oxide, silicon nitride, amorphous silicon, or the like may also be additionally formed on the substrate 110.

A buffer layer 120 may be formed on the substrate 110. The buffer layer 120 may provide a flat surface on the substrate 110, and may prevent impurities from penetrating through the substrate 110.

The amorphous silicon layer 132 may be formed on the buffer layer 120. The amorphous silicon layer 132 may be formed by a method such as low pressure chemical vapor deposition (LPCVD), atmospheric pressure chemical vapor deposition (APCVD), plasma enhanced chemical vapor deposition (PECVD), sputtering, vacuum evaporation, or the like. A native oxide layer may be formed on the amorphous silicon layer 132.

As shown in FIG. 13, a silicon oxide layer TOL may be formed on a surface of the amorphous silicon layer 132. The silicon oxide layer TOL may be formed on the amorphous silicon layer 132 through impurity doping. Impurities IMP may be a Group V element. In an embodiment, the impurities IMP may be phosphorus (P). The impurities IMP may be doped on the entire surface of the amorphous silicon layer 132.

The impurities IMP may be doped through an ion implantation method. When using the ion implantation method, the impurities IMP in an ionic state are accelerated to tens to several hundreds keV and implanted into the amorphous silicon layer 132. A dose of the impurities IMP may be 1.0 e¹² to 1.0 e¹³ per cm³.

The impurities IMP may induce bonding between silicon (Si) in the amorphous silicon layer 132 and oxygen (O) in the native oxide layer NOL to form the silicon oxide layer TOL between the native oxide layer NOL and the amorphous silicon layer 132.

The amorphous silicon layer 132 may be cleaned using hydrofluoric acid. For example, the hydrofluoric acid may contain about 0.5% hydrogen fluoride. The native oxide layer formed on the amorphous silicon layer 132 may be removed by cleaning the amorphous silicon layer 132 with the hydrofluoric acid. In an embodiment, the amorphous silicon layer 132 may be cleaned by the hydrofluoric acid for about 40 seconds to about 54 seconds.

The amorphous silicon layer 132 may be rinsed using hydrogen-added deionized water. For example, the hydrogen-added deionized water may have a hydrogen concentration of about 1.0 ppm. The amorphous silicon layer 132 may be rinsed with the hydrogen-added deionized water to remove the hydrofluoric acid remaining on the amorphous silicon layer 132.

Referring to FIG. 14, a polycrystalline silicon layer 134 may be formed by crystallizing the amorphous silicon layer 132.

The polycrystalline silicon layer 134 may be formed by irradiating a laser beam onto the amorphous silicon layer 132. A laser may intermittently generate the laser beam to irradiate the amorphous silicon layer 132.

The laser may irradiate a laser beam having an energy density of about 450 mJ/cm2 to about 500 mJ/cm2 onto the amorphous silicon layer 132. In an embodiment, a width of the laser beam may be about 480 μm, and a scan pitch of the laser beam may be about 9 μm to about 30 μm.

When the laser beam is irradiated onto the amorphous silicon layer 132 that is in a solid state, the amorphous silicon layer 132 may absorb heat to change to a liquid state, and then may discharge heat to change to the solid state again. In this case, a crystal may grow from a crystal seed to form a grain. When there is a difference in cooling rate in a process of changing the amorphous silicon layer 132 from the liquid state to the solid state, a grain boundary may be formed in a region having a low cooling rate because the grain grows from a region having a high cooling rate toward a region having a low cooling rate.

A plurality of grains may be formed in the polycrystalline silicon layer 134. The grains may be randomly arranged on a plane. The grains may be formed to have a size of about 150 nm to about 200 nm.

A protrusion may be formed at the grain boundary on the surface of the polycrystalline silicon layer 134 on which the crystallization process has been performed. The protrusion may protrude upward from the surface of the polycrystalline silicon layer 134, and may have a pointed shape. The protrusion may have a constant thickness corresponding to a distance from the surface of the polycrystalline silicon layer 134 to an end of the protrusion.

An effective value of a surface roughness of the polycrystalline silicon layer 134 may be about 4 nm or less. In this case, the effective value of thicknesses of the protrusions formed on the surface of the polycrystalline silicon layer 134 may be about 4 nm or less.

Then, the polycrystalline silicon layer 134 may be etched to form a polycrystalline silicon pattern 136. The polycrystalline silicon layer 134 may be etched by photolithography. For example, a photoresist pattern may be formed on the polycrystalline silicon layer 134 using an exposure process and a development process, and the polycrystalline silicon layer 134 may be etched using the photoresist pattern as an etch stop film.

Referring to FIG. 15, a gate insulating film 140 may be formed on the polycrystalline silicon pattern 136. The gate insulating film 140 may be disposed on the buffer layer 120 to cover the polycrystalline silicon pattern 136. The gate insulating film 140 may insulate a gate electrode GE from the polycrystalline silicon pattern 136. For example, the gate insulating film 140 may be formed of silicon oxide, silicon nitride, or the like.

In an embodiment, the polycrystalline silicon pattern 136 having an effective value of the surface roughness of about 4 nm or less may be formed, so that the polycrystalline silicon pattern 136 has a relatively small surface roughness. Accordingly, the influence on the gate insulating film 140 formed on the polycrystalline silicon pattern 136 by the protrusions formed on the surface of the polycrystalline silicon pattern 136 may be minimized, and the gate insulating film 140 may be formed to have a relatively thin thickness. For example, the gate insulating film 140 may be formed to have a thickness of about 30 nm to about 200 nm.

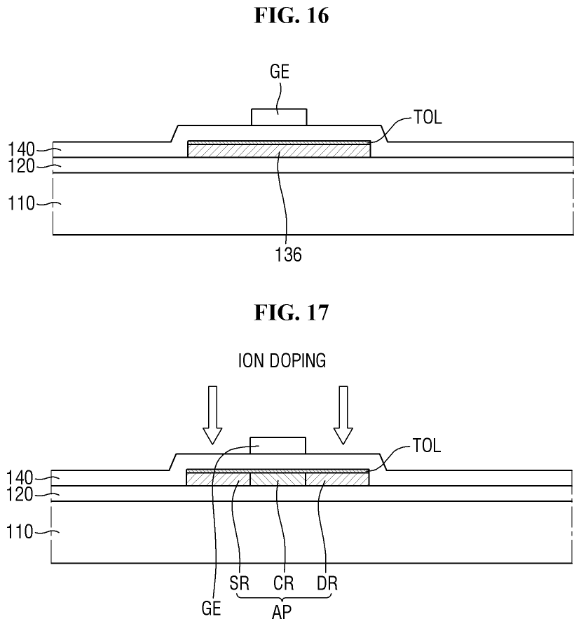

Referring to FIG. 16, the gate electrode GE may be formed on the gate insulating film 140.

The gate electrode GE may overlap the polycrystalline silicon pattern 136. The gate electrode GE may contain gold (Au), silver (Ag), aluminum (Al), copper (Cu), nickel (Ni) platinum (Pt), magnesium (Mg), chromium (Cr), tungsten (W), molybdenum (Mo), titanium (Ti), or an alloy thereof, and may have a structure of a single layer or multiple layers including different metal layers. For example, the gate electrode GE may include a triple layer of molybdenum/aluminum/molybdenum, a double layer of copper/titanium, or the like.

For example, a photoresist pattern overlapping a first metal layer and the polycrystalline silicon pattern 136 may be formed on the gate insulating film 140. Then, the gate electrode GE may be formed by etching the first metal layer using the photoresist pattern.

Referring to FIG. 17, an active pattern AP may be formed by partially implanting ions into the polycrystalline silicon pattern 136.

The active pattern AP including a source region SR, a channel region CR, and a drain region DR may be formed by partially doping the polycrystalline silicon pattern 136 through an ion implantation process. The ions may be n-type impurities or p-type impurities.

A portion of the polycrystalline silicon pattern 136 overlapping the gate electrode GE may remain without doping ions to form the channel region CR. An ion-doped portion of the polycrystalline silicon pattern 136 has the properties of a conductor due to an increase in conductivity, so that the source region SR and the drain region DR may be formed. The channel region CR may be formed between the source region SR and the drain region DR.

In another embodiment, a low-concentration doped region may be respectively formed between the channel region CR and the source region SR, and between the channel region CR and the drain region DR by doping impurities at a lower concentration than the ion implantation process. The low-concentration doped region serves as a buffer in the active pattern AP, thereby improving electrical properties of the thin film transistor.

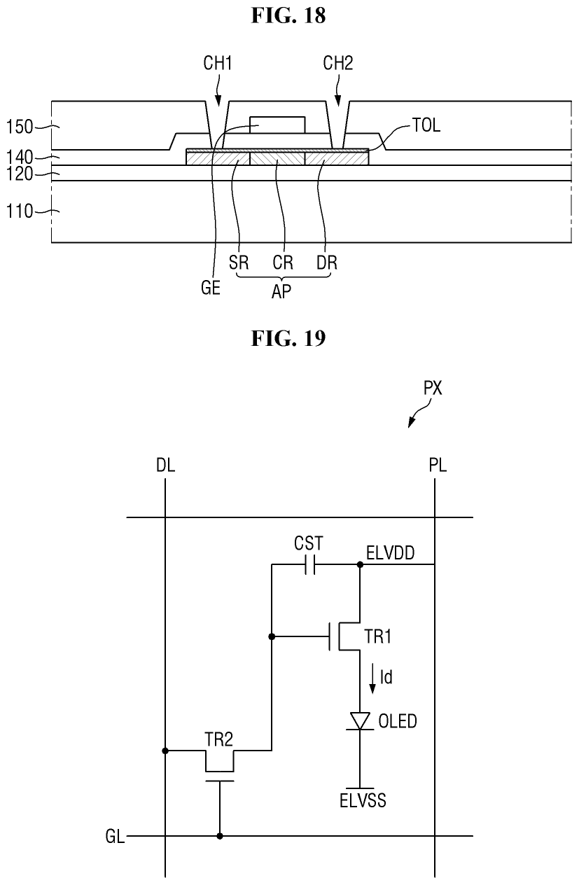

Referring to FIG. 18, an interlayer insulating film 150 may be formed on the gate electrode GE. The interlayer insulating film 150 may be disposed on the gate insulating film 140 to cover the gate electrode GE. The interlayer insulating film 150 may insulate a source electrode SE and a drain electrode DE from the gate electrode GE.

The interlayer insulating film 150 may include an inorganic insulating layer, an organic insulating layer, or a combination thereof. For example, the interlayer insulating film 150 may contain silicon oxide, silicon nitride, silicon carbide, or a combination thereof, and may contain an insulating metal oxide such as aluminum oxide, tantalum oxide, hafnium oxide, zirconium oxide, or titanium oxide. When the interlayer insulating film 150 includes an organic insulating layer, the interlayer insulating film 150 may contain polyimide, polyamide, acrylic resin, phenolic resin, benzocyclobutene (BCB), or the like.

Thereafter, the interlayer insulating film 150 and the gate insulating film 140 may be partially etched to form a first contact hole CH1 and a second contact hole CH2 exposing each of the source region SR and the drain region DR.

Referring to FIG. 11, the source electrode SE and the drain electrode DE electrically connected to the source region SR and the drain region DR of the active pattern AP, respectively, may be formed on the interlayer insulating film 150.

For example, a second metal layer may be formed on the interlayer insulating film 150 and patterned to form the source electrode SE in contact with the source region SR and the drain electrode DE in contact with the drain region DR. For example, each of the source electrode SE and the drain electrode DE may contain gold (Au), silver (Ag), aluminum (Al), copper (Cu), nickel (Ni) platinum (Pt), magnesium (Mg), chromium (Cr), tungsten (W), molybdenum (Mo), titanium (Ti), or an alloy thereof, and may have a structure of a single layer or multiple layers including different metal layers. For example, each of the source electrode SE and the drain electrode DE may include a triple layer of molybdenum/aluminum/molybdenum, a double layer of copper/titanium, or the like.

According to an embodiment, the thin film transistor TR in which characteristics such as distribution of a threshold voltage, hysteresis, and the like are improved may be formed by performing the cleaning process using the hydrofluoric acid and the rinsing process using the hydrogen-added deionized water before the crystallization process.

Hereinafter, a display device and a method of manufacturing the same according to an embodiment will be described with reference to FIGS. 19 to 22.

FIG. 19 is a circuit diagram showing one pixel of the display device according to an embodiment.

Referring to FIG. 19, the display device according to an embodiment may include signal lines GL, DL, and PL, and a plurality of pixels PX connected thereto and arranged in a substantially matrix form.

The signal lines GL, DL, and PL may include gate lines GL transmitting a gate signal (or scan signal), data lines DL transmitting a data voltage, and driving voltage lines PL transmitting a driving voltage ELVDD. The gate lines GL may extend in a substantially row direction. The data lines DL and the driving voltage lines PL may cross the gate lines GL, and may extend in a substantially column direction. Each pixel PX may include a driving transistor TR1, a switching transistor TR2, a storage capacitor CST, and an organic light-emitting diode OLED.

The driving transistor TR1 may include a control terminal, an input terminal, and an output terminal. The control terminal may be connected to the switching transistor TR2. The input terminal may be connected to the driving voltage line PL. The output terminal may be connected to the organic light-emitting diode OLED. The driving transistor TR1 may transmit an output current Id, of which magnitude changes according to a voltage applied between the control terminal and the output terminal, to the organic light-emitting diode OLED.

The switching transistor TR2 may include a control terminal, an input terminal, and an output terminal. The control terminal may be connected to the gate line GL. The input terminal may be connected to the data line DL. The output terminal may be connected to the driving transistor TR1. The switching transistor TR2 may transmit the data voltage applied to the data line DL to the driving transistor TR1 in response to the gate signal applied to the gate line GL.

The storage capacitor CST may be connected between the control terminal and the input terminal of the driving transistor TR1. The storage capacitor CST may charge the data voltage applied to the control terminal of the driving transistor TR1, and may maintain the data voltage even after the switching transistor TR2 is turned off.

The organic light-emitting diode OLED may include an anode connected to the output terminal of the driving transistor TR1 and a cathode connected to a common voltage ELVSS. The organic light-emitting diode OLED may display an image by emitting light with different brightness according to the output current Id of the driving transistor TR1.

In an embodiment, each pixel PX may include two thin film transistors TR1 and TR2 and one capacitor CST, but the present disclosure is not limited thereto. In another embodiment, each pixel PX may include three or more thin film transistors or two or more capacitors.

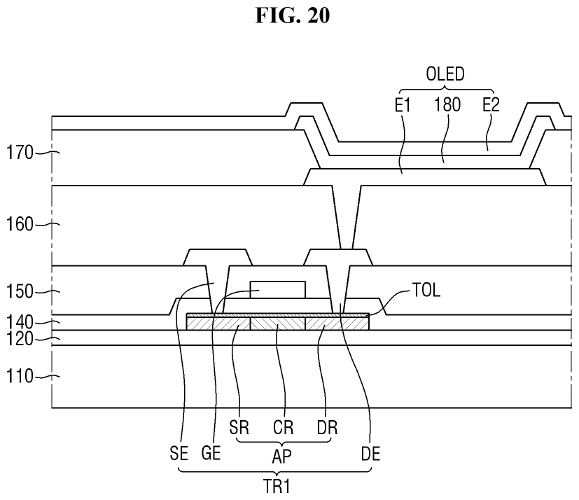

FIG. 20 is a cross-sectional view showing the display device according to an embodiment.

Referring to FIG. 20, the display device according to an embodiment may include a substrate 110, a thin film transistor disposed on the substrate 110, and a display element disposed on the thin film transistor. In an embodiment, the display device may include an organic light-emitting diode as the display element. However, the embodiment described herein is not limited thereto, and in another embodiment, the display device may include a liquid crystal element, an electrophoretic element, an electrowetting element, and the like as the display element.

Each of a thin film transistor TR1 and an organic light-emitting diode OLED shown in FIG. 20 may correspond to the driving transistor TR1 and the organic light-emitting diode OLED shown in FIG. 19. The display device according to an embodiment may include the thin film transistor substrate 100 according to the embodiment illustrated in FIG. 11.

The organic light-emitting diode OLED may include a first electrode E1, an organic light-emitting layer 180, and a second electrode E2 that are sequentially stacked. The organic light-emitting diode OLED may emit light based on a driving current transmitted from the thin film transistor TR1 to display an image.

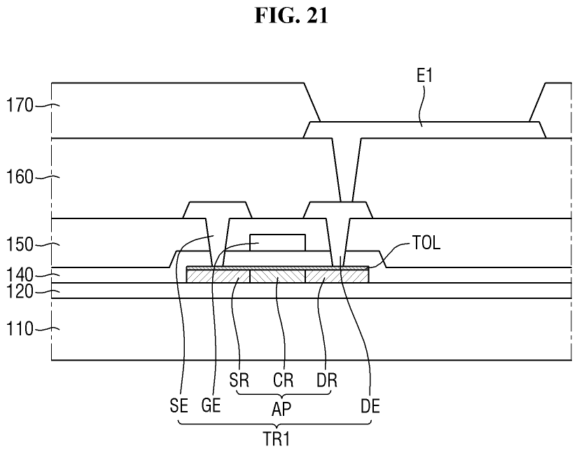

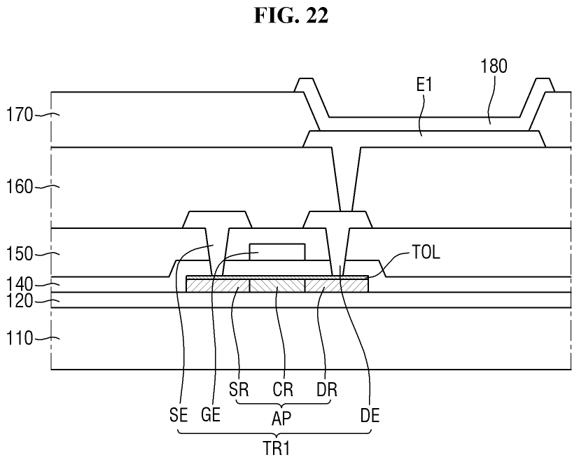

FIGS. 21 and 22 are cross-sectional views showing a method of manufacturing the display device of FIG. 20.

Hereinafter, in describing the method of manufacturing the display device according to an embodiment, a description of a portion overlapping the method of manufacturing the thin film transistor substrate according to an embodiment will be omitted for ease in explanation of the embodiment.

Referring to FIG. 21, the first electrode E1 may be formed on the thin film transistor TR1.

First, a planarization film (or protective film) 160 may be formed on a source electrode SE and a drain electrode DE. The planarization film 160 may be disposed on an interlayer insulating film 150 to cover the source electrode SE and the drain electrode DE. The planarization film 160 may insulate the first electrode E1 from the source electrode SE and the drain electrode DE.

The planarization film 160 may include an organic insulating layer, an inorganic insulating layer, or a combination thereof. For example, the planarization film 160 may have a structure of a single layer or multiple layers containing silicon nitride or silicon oxide. When the planarization film 160 includes an organic insulating layer, the planarization film 160 may contain polyimide, acrylic resin, phenolic resin, benzocyclobutene (BCB), polyamide, or the like.

Thereafter, the planarization film 160 may be patterned to form a contact hole exposing the drain electrode DE.

Thereafter, the first electrode E1 electrically connected to the drain electrode DE may be formed on the planarization film 160. For example, a third metal layer may be formed on the planarization film 160 and patterned to form the first electrode E1 in contact with the drain electrode DE.

The first electrode E1 may be a pixel electrode of the display device. The first electrode E1 may be formed as a transmissive electrode or as a reflective electrode depending on the light-emitting type. When the first electrode E1 is formed as the transmissive electrode, the first electrode E1 may include indium tin oxide (ITO), indium zinc oxide (IZO), zinc tin oxide (ZTO), indium oxide (In₂O₃), zinc oxide (ZnO), tin oxide (SnO₂), or the like. When the first electrode E1 is formed as the reflective electrode, the first electrode E1 may include gold (Au), silver (Ag), aluminum (Al), copper (Cu), nickel (Ni), platinum (Pt), magnesium (Mg), chromium (Cr), tungsten (W), molybdenum (Mo), titanium (Ti), or the like, and may have a stacked structure with a material used for the transmissive electrode.

Thereafter, a pixel-defining film 170 may be formed on the planarization film 160. The pixel-defining film 170 may have an opening exposing at least a portion of the first electrode E1. For example, the pixel-defining film 170 may include an organic insulating material.

Referring to FIG. 22, the organic light-emitting layer 180 may be formed on the first electrode E1.

The organic light-emitting layer 180 may be formed on an upper surface of the first electrode E1 exposed by the opening of the pixel-defining film 170. For example, the organic light-emitting layer 180 may be formed by a method such as screen printing, inkjet printing, or vapor deposition.

The organic light-emitting layer 180 may contain a low molecular weight organic compound or a high molecular weight organic compound. For example, the organic light-emitting layer 180 may contain copper phthalocyanine, N, N′-diphenylbenzidine, tris(8-hydroxyquinoline)aluminum, and the like as the low molecular organic compound. In addition, the organic light-emitting layer 180 may contain poly(3,4-ethylenedioxythiophene), polyaniline, poly-phenylenevinylene, polyfluorene, and the like as the high molecular weight organic compound.

In an embodiment, the organic light-emitting layer 180 may emit red, green, or blue light. In another embodiment, when the organic light-emitting layer 180 emits white light, the organic light-emitting layer 180 may include a multi-layer structure including a red light-emitting layer, a green light-emitting layer, and a blue light-emitting layer, or may include a single layer structure containing a red light-emitting material, a green light-emitting material, and a blue light-emitting material.

In an embodiment, a hole injection layer and/or a hole transport layer may be further formed between the first electrode E1 and the organic light-emitting layer 180, or an electron transport layer and/or an electron injection layer may be further formed on the organic light-emitting layer 180.

Referring to FIG. 20, the second electrode E2 may be formed on the organic light-emitting layer 180.

The second electrode E2 may be a common electrode of the display device. The second electrode E2 may be formed as a transmissive electrode or as a reflective electrode depending on the light-emitting type of the display device. For example, when the second electrode E2 is formed as the transmissive electrode, the second electrode E2 may contain lithium (Li), calcium (Ca), lithium fluoride (LiF), aluminum (Al), magnesium (Mg), or a combination thereof.

The display device may be a top light-emitting type in which light is emitted in a direction of the second electrode E2, but the embodiment described herein is not limited thereto, and the display device may also be a bottom light-emitting type.

According to a method of manufacturing a polycrystalline silicon layer, a display device, and a method of manufacturing the display device according to an embodiment, circular stains of the polycrystalline silicon layer (or active pattern) can be improved.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A method of manufacturing a polycrystalline silicon layer, the method comprising:
forming an amorphous silicon layer on a substrate;
doping the amorphous silicon layer with at least one impurity;
cleaning the amorphous silicon layer with hydrofluoric acid;
rinsing the amorphous silicon layer with hydrogen-added deionized water; and
forming a polycrystalline silicon layer by irradiating a laser beam onto the amorphous silicon layer.

2. The method of claim 1, wherein the at least one impurity includes phosphorus (P), and is doped on an entire surface of the amorphous silicon layer.

3. The method of claim 2, wherein the at least one impurity is doped through an ion implantation method, and
a dose of the at least one impurity is 1.0 e¹² to 1.0 e¹³ per cm³.

4. The method of claim 2, wherein a native oxide layer is formed on the amorphous silicon layer, and
the at least one impurity induces bonding between silicon (Si) in the amorphous silicon layer and oxygen (O) in the native oxide layer to form a silicon oxide layer between the native oxide layer and the amorphous silicon layer.

5. The method of claim 4, wherein the native oxide layer is removed in the cleaning of the amorphous silicon layer, and
the silicon oxide layer is not removed.

6. The method of claim 1, wherein the hydrofluoric acid contains about 0.5% hydrogen fluoride.

7. The method of claim 1, wherein the amorphous silicon layer is cleaned for 40 seconds to 54 seconds.

8. The method of claim 1, wherein the hydrogen-added deionized water has a hydrogen concentration of about 1.0 ppm.

9. The method of claim 1, wherein an energy density of the laser beam ranges from 450 mJ/cm² to 500 mJ/cm².

10. The method of claim 1, wherein a width of the laser beam is about 480 μm, and
a scan pitch of the laser beam ranges from 9 μm to 30 μm.

11. The method of claim 1, wherein an effective value of a surface roughness of the polycrystalline silicon layer is 4 nm or less.

12. The method of claim 1, wherein a protrusion is formed on a surface of the polycrystalline silicon layer, and the protrusion has a pointed shape.

13. The method of claim 1, wherein grains of the polycrystalline silicon layer are randomly arranged.

14. A display device comprising:
a substrate;
a thin film transistor disposed on the substrate; and
a display element disposed on the thin film transistor,
wherein the thin film transistor includes:
an active pattern disposed on the substrate;
a gate insulating film disposed on the active pattern;
a silicon oxide layer disposed between the active pattern and the gate insulating film; and
a gate electrode disposed on the gate insulating film,
wherein an effective value of a surface roughness of the active pattern is 4 nm or less.

15. The display device of claim 14, wherein the active pattern includes a source region, a drain region, and a channel region formed therebetween.

16. The display device of claim 15, wherein the gate electrode overlaps the channel region of the active pattern.

17. The display device of claim 15, wherein the thin film transistor is disposed on the gate electrode, and
the thin film transistor further includes a source electrode and a drain electrode electrically connected to the source region and the drain region of the active pattern, respectively.

18. The display device of claim 14, wherein the display element includes:
a first electrode electrically connected to the thin film transistor; an organic light-emitting layer disposed on the first electrode; and a second electrode disposed on the organic light-emitting layer.

19. A method of manufacturing a display device, the method comprising:
forming an amorphous silicon layer on a substrate;
doping the amorphous silicon layer with at least one impurity;
cleaning the amorphous silicon layer with hydrofluoric acid;
rinsing the amorphous silicon layer with hydrogen-added deionized water;
forming a polycrystalline silicon layer by irradiating a laser beam onto the amorphous silicon layer;
etching the polycrystalline silicon layer and forming a polycrystalline silicon pattern;
forming a gate insulating film on the polycrystalline silicon pattern;
forming a gate electrode on the gate insulating film;
partially implanting ions into the polycrystalline silicon pattern and forming an active pattern; and
forming a display element on the gate electrode.

20. The method of claim 19, wherein the at least one impurity includes phosphorus (P) and is doped on an entire surface of the amorphous silicon layer, the at least one impurity is doped through an ion implantation method, and a dose of the at least one impurity is 1.0 e¹² to 1.0 e¹³ per cm³.
